(19) United States
(12) Patent Application Publication
(10) Pub. No.: US 2025/0285968 A1
(43) Pub. Date: Sep. 11, 2025

(54) BACKSIDE POWER DISTRIBUTION NETWORK

(71) Applicant: International Business Machines Corporation, Armonk, NY (US)

(72) Inventors: Ruilong Xie, Niskayuna, NY (US); Reinaldo Vega, Mahopac, NY (US); Nicholas Anthony Lanzillo, Wynantskill, NY (US); Brent A. Anderson, Jericho, VT (US); Lawrence A. Clevenger, Saratoga Springs, NY (US); Albert M. Chu, Nashua, NH (US); Kisik Choi, Watervliet, NY (US)

(21) Appl. No.: 18/595,717

(22) Filed: Mar. 5, 2024

(51) Int. Cl. H01L 23/528; H01L 27/092; H01L 29/06; H01L 29/423; H01L 29/775; H01L 29/786

(52) U.S. Cl. CPC H01L 23/5283; H10D 30/43; H10D 30/6735; H10D 30/6757; H10D 62/121; H10D 84/853

(57) ABSTRACT

A semiconductor structure includes a backside interconnect comprising a first metal layer and a second metal layer disposed on the first metal layer, the first metal layer comprising a first Vdd metal line and a first Vss metal line, and the second metal layer comprising a second Vdd metal line and a second Vss metal line, the first Vss metal line being in contact with the second Vss metal line and the second Vss metal line being isolated from the first Vdd metal line by a non-conductive liner.

### BACKGROUND

Semiconductors and integrated circuit chips have become ubiquitous within many products, particularly as they continue to decrease in cost and size. There is a continued desire to reduce the size of structural features and/or to provide a greater number of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Illustrative embodiments of the present application include techniques for use in semiconductor manufacture. In an illustrative embodiment, a semiconductor structure comprises a backside interconnect comprising a first metal layer and a second metal layer disposed on the first metal layer, the first metal layer comprising a first Vdd metal line and a first Vss metal line, and the second metal layer comprising a second Vdd metal line and a second Vss metal line. The first Vss metal line is in contact with the second Vss metal line and the second Vss metal line is isolated from the first Vdd metal line by a non-conductive liner.

In another illustrative embodiment, a semiconductor structure comprises a backside interconnect comprising a first metal layer and a second metal layer disposed on the first metal layer, the first metal layer comprising a first Vdd metal line, and the second metal layer comprising a second Vdd metal line and a Vss metal line. The first Vdd metal line is in contact with the second Vdd metal line and the first Vdd metal line is isolated from the Vss metal line by a non-conductive liner.

In yet another illustrative embodiment, an integrated circuit comprises one or more semiconductor devices. At least one of the one or more semiconductor devices is a semiconductor device according to one or more of the foregoing illustrative embodiments.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1A is a cross-sectional view of a semiconductor structure taken along the Y-Y axis of FIG. 1C for use at a first-intermediate fabrication stage, according to an illustrative embodiment.

FIG. 1B is a cross-sectional view of the semiconductor structure taken along the X-X axis of FIG. 1C for use at the first-intermediate fabrication stage, according to an illustrative embodiment.

FIG. 1C is a top-down view of the semiconductor structure for use at the first intermediate fabrication stage, according to an illustrative embodiment.

FIG. 2A is a cross-sectional view of the semiconductor structure taken along the Y-Y axis of FIG. 1C for use at a second-intermediate fabrication stage, according to an illustrative embodiment.

FIG. 2B is a cross-sectional view of the semiconductor structure taken along the X-X axis of FIG. 1C for use at the second-intermediate fabrication stage, according to an illustrative embodiment.

FIG. 3A is a cross-sectional view of the semiconductor structure taken along the Y-Y axis of FIG. 1C for use at a third-intermediate fabrication stage, according to an illustrative embodiment.

FIG. 3B is a cross-sectional view of the semiconductor structure taken along the X-X axis of FIG. 1C for use at the third-intermediate fabrication stage, according to an illustrative embodiment.

FIG. 4A is a cross-sectional view of the semiconductor structure taken along the Y-Y axis of FIG. 1C for use at a fourth-intermediate fabrication stage, according to an illustrative embodiment.

FIG. 4B is a cross-sectional view of the semiconductor structure taken along the X-X axis of FIG. 1C for use at the fourth-intermediate fabrication stage, according to an illustrative embodiment.

FIG. 5A is a cross-sectional view of the semiconductor structure taken along the Y-Y axis of FIG. 1C for use at a fifth-intermediate fabrication stage, according to an illustrative embodiment.

FIG. 5B is a cross-sectional view of the semiconductor structure taken along the X-X axis of FIG. 1C for use at the fifth-intermediate fabrication stage, according to an illustrative embodiment.

FIG. 6A is a cross-sectional view of the semiconductor structure taken along the Y-Y axis of FIG. 1C for use at a sixth-intermediate fabrication stage, according to an illustrative embodiment.

FIG. 6B is a cross-sectional view of the semiconductor structure taken along the X-X axis of FIG. 1C for use at the sixth-intermediate fabrication stage, according to an illustrative embodiment.

FIG. 7A is a cross-sectional view of the semiconductor structure taken along the Y-Y axis of FIG. 1C for use at a seventh-intermediate fabrication stage, according to an illustrative embodiment.

FIG. 7B is a cross-sectional view of the semiconductor structure taken along the X-X axis of FIG. 1C for use at the seventh-intermediate fabrication stage, according to an illustrative embodiment.

FIG. 8A is a cross-sectional view of the semiconductor structure taken along the Y-Y axis of FIG. 1C for use at an eighth-intermediate fabrication stage, according to an illustrative embodiment.

FIG. 8B is a cross-sectional view of the semiconductor structure taken along the X-X axis of FIG. 1C for use at the eighth-intermediate fabrication stage, according to an illustrative embodiment.

FIG. 9A is a cross-sectional view of the semiconductor structure taken along the Y-Y axis of FIG. 1C for use at a ninth-intermediate fabrication stage, according to an illustrative embodiment.

FIG. 9B is a cross-sectional view of the semiconductor structure taken along the X-X axis of FIG. 1C for use at the ninth-intermediate fabrication stage, according to an illustrative embodiment.

FIG. 10A is a cross-sectional view of the semiconductor structure taken along the Y-Y axis of FIG. 1C for use at a tenth-intermediate fabrication stage, according to an illustrative embodiment.

FIG. 10B is a cross-sectional view of the semiconductor structure taken along the X-X axis of FIG. 1C for use at the tenth-intermediate fabrication stage, according to an illustrative embodiment.

FIG. 11A is a cross-sectional view of the semiconductor structure taken along the Y-Y axis of FIG. 1C starting from FIG. 5A for use at a first-intermediate fabrication stage, according to an alternative illustrative embodiment.

FIG. 11B is a cross-sectional view of the semiconductor structure taken along the X-X axis of FIG. 1C for use at the first-intermediate fabrication stage, according to an alternative illustrative embodiment.

FIG. 12A is a cross-sectional view of the semiconductor structure taken along the Y-Y axis of FIG. 1C for use at a second-intermediate fabrication stage, according to an alternative illustrative embodiment.

FIG. 12B is a cross-sectional view of the semiconductor structure taken along the X-X axis of FIG. 1C for use at the second-intermediate fabrication stage, according to an alternative illustrative embodiment.

FIG. 13A is a cross-sectional view of the semiconductor structure taken along the Y-Y axis of FIG. 1C for use at a third-intermediate fabrication stage, according to an alternative illustrative embodiment.

FIG. 13B is a cross-sectional view of the semiconductor structure taken along the

X-X axis of FIG. 1C for use at the third-intermediate fabrication stage, according to an alternative illustrative embodiment.

FIG. 14A is a cross-sectional view of the semiconductor structure taken along the Y-Y axis of FIG. 1C for use at a fourth-intermediate fabrication stage, according to an alternative illustrative embodiment.

FIG. 14B is a cross-sectional view of the semiconductor structure taken along the X-X axis of FIG. 1C for use at the fourth-intermediate fabrication stage, according to an alternative illustrative embodiment.

FIG. 15A is a cross-sectional view of the semiconductor structure taken along the Y-Y axis of FIG. 1C for use at a fifth-intermediate fabrication stage, according to an alternative illustrative embodiment.

FIG. 15B is a cross-sectional view of the semiconductor structure taken along the X-X axis of FIG. 1C for use at the fifth-intermediate fabrication stage, according to an alternative illustrative embodiment.

FIG. 16A is a cross-sectional view of the semiconductor structure taken along the Y-Y axis of FIG. 1C for use at a sixth-intermediate fabrication stage, according to an alternative illustrative embodiment.

FIG. 16B is a cross-sectional view of the semiconductor structure taken along the X-X axis of FIG. 1C for use at the sixth-intermediate fabrication stage, according to an alternative illustrative embodiment.

FIG. 17A is a cross-sectional view of the semiconductor structure taken along the Y-Y axis of FIG. 1C for use at a seventh-intermediate fabrication stage, according to an alternative illustrative embodiment.

FIG. 17B is a cross-sectional view of the semiconductor structure taken along the X-X axis of FIG. 1C for use at the seventh-intermediate fabrication stage, according to an alternative illustrative embodiment.

FIG. 18A is a cross-sectional view of the semiconductor structure taken along the Y-Y axis of FIG. 1C for use at an eighth-intermediate fabrication stage, according to an alternative illustrative embodiment.

FIG. 18B is a cross-sectional view of the semiconductor structure taken along the X-X axis of FIG. 1C for use at the eighth-intermediate fabrication stage, according to an alternative illustrative embodiment.

### DETAILED DESCRIPTION

This disclosure relates generally to semiconductor devices, and more particularly to semiconductor structures having a backside power distribution network, and methods for their fabrication. However, it is to be understood that embodiments of the present disclosure are not limited to the illustrative methods, apparatus, systems and devices but instead are more broadly applicable to other suitable methods, apparatus, systems and devices.

A semiconductor device can include multiple metallization levels (“levels”), each including a conductive line (“line”) formed in an interlayer dielectric layer (ILD). Although the term metallization is used herein, metallization levels can be formed to include any suitable conductive material in accordance with the embodiments described herein. Levels can be identified herein using the designation X, where X is a positive integer from 1 to N. The levels are identified from the level closest to the substrate to the level furthest from the substrate as 1 through N where 1 is the first or lowermost level and N is the last or uppermost level. A line in the X level is designated as an Mₓ line. When a line in an upper level is designated Mx, then a line in an immediately lower level can be designated M₍ₓ₋1). Likewise, when a line in a lower level is designated Mx, then a line in an immediately higher level is designated M_{(X+)}. For a first level (X=1), the line is M₁. For a second level (X=2), the line is M₂ and, for a third level (X=3), the line is M₃.

Detailed embodiments of the semiconductor structures and methods are disclosed herein. The method steps described below do not form a complete process flow for manufacturing integrated circuits, such as, semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element.

As used herein, “lateral,” “lateral side,” “lateral surface” refers to a side surface of an element (e.g., a layer, opening, etc.), such as a left or right-side surface in the drawings.

As used herein, “width” or “length” refers to a size of an element (e.g., a layer, trench, hole, opening, etc.) in the drawings measured from a side surface to an opposite surface of the element.

As used herein, terms such as “upper”, “lower”, “right”, “left”, “vertical”, “horizontal”, “top”, “bottom”, and derivatives thereof are to be broadly construed to relate to the disclosed structures and methods, as oriented in the drawings, wherein such structures may be understood to have the same configuration (e.g., layers stacked in the same order) even if the structure is rotated to a different angle from that shown in the drawings.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop” or the term “direct contact” mean that a first element and a second element are connected without any intervening elements, such as, for example, intermediary conducting, insulating or semiconductor layers, present between the first element and the second element.

It is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another clement. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include, but are not limited to, physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s).

In the IC chip fabrication industry, there are three sections referred to in a typical IC chip build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. Accordingly, illustrative embodiments described herein may be directed to BEOL semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than 10 metal layers may be added in the BEOL. The conductive contacts of the MOL layer provide electrical connections between the integrated circuitry of the FEOL layer and a first level of metallization of a BEOL structure that is formed over the FEOL/MOL layers.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

Conventional backside interconnects have signal lines and power wires that are mixed. Typically, a via is needed to separate metal lines between neighboring levels to make sure that resistance and capacitance is optimized. However, for a backside power delivery network, only power wires exist and there are no signal lines. Therefore, it is desirable to increase coupling capacitance between Vdd and Vss units, and to reduce the resistance to a minimum to improve voltage drop. Voltage drop (or IR drop) is a phenomenon that occurs in a semiconductor's power delivery network when current flows through a resistor, causing the voltage to drop. Illustrative embodiments overcome the foregoing drawback by providing methods and structures for enabling a via-less backside power distribution network (i.e., a backside power distribution network without vias between the metal lines of the metallization layers).

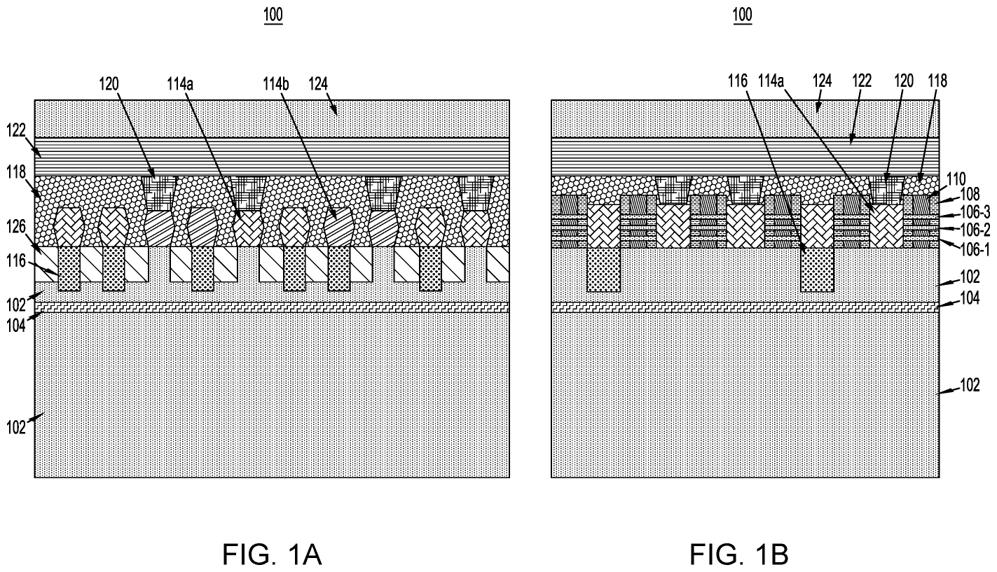

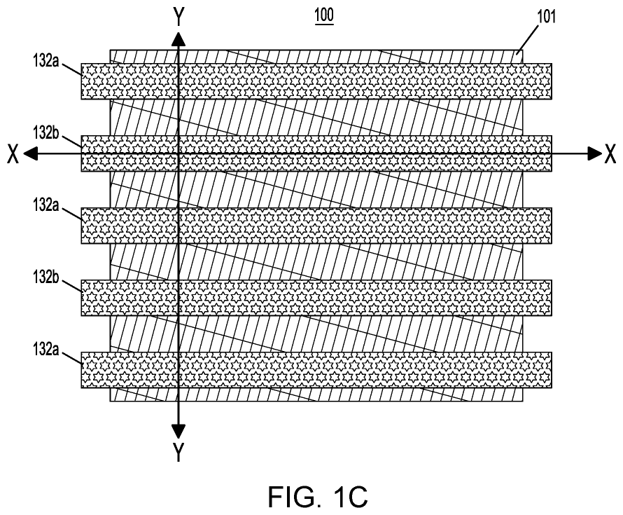

Referring now to the drawings in which like numerals represent the same or similar elements, FIGS. 1A-18B illustrate various processes for fabricating semiconductor structures with a backside power distribution network. Note that the same reference numeral (100) is used to denote the semiconductor structure through the various intermediate fabrication stages illustrated in FIGS. 1A-18B. Note also that the semiconductor structures described herein can also be considered to be a semiconductor device and/or an integrated circuit, or some part thereof. For the purpose of clarity, some fabrication steps leading up to the production of the semiconductor structures as illustrated in FIGS. 1A-18B are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

Referring now to FIG. 1A-10B, FIG. 1A shows a cross-sectional view of a semiconductor structure 100, FIG. 1B shows a cross-sectional view of semiconductor structure 100 and FIG. 1C shows a top-down view of semiconductor structure 100. The top-down view of FIG. 1C shows an active region 101 where backside power (Vdd) rails 132a (also referred to as backside Vdd metal lines) and backside ground (Vss) rails 132b (also referred to as backside Vss metal lines) will be formed. The cross-sectional view of FIG. 1A is taken along the line Y-Y in the top-down view (e.g., across backside power (Vdd) rails 132a and backside ground (Vss) rails 132b) and further across source/drain regions 114a and 114b, and the cross-sectional view of FIG. 1B is taken along the line X-X in the top-down view (e.g., along the backside ground (Vss) rails 132b) and further across a gate stack layer 110.

Semiconductor structure 100 shows a substrate 102. Substrate 102 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. In one illustrative embodiment, substrate 102 is silicon.

An etch stop layer 104 is formed in substrate 102. Etch stop layer 104 may comprise a buried oxide (BOX) layer or silicon germanium (SiGe), or another suitable material such as a III-V semiconductor epitaxial layer.

Semiconductor structure 100 further shows nanosheet channel layers 106-1, 106-2 and 106-3 (collectively, nanosheet channel layers 106). Nanosheet channel layers 106 may be formed of Si or another suitable material (e.g., a material similar to that used for substrate 102).

Semiconductor structure 100 further shows STI regions 126 in substrate 102. STI regions 126 may be formed of a dielectric material such as silicon dioxide (SiO₂), silicon oxycarbide (SiOC), silicon oxynitride (SiON), etc.

Semiconductor structure 100 further includes gate spacers 108, a gate stack layer 110, source/drain regions 114a and 114b, sacrificial placeholder layers 116 and an interlayer dielectric (ILD) layer 118.

Gate spacers 108 may be formed of any suitable insulator, such as SiN, silicon boron carbide nitride (SiBCN), silicon oxycarbonitride (SiOCN), etc. Gate spacers 108 may be formed to fill indent spaces (e.g., resulting from indent etches of sacrificial layers prior to their removal).

Gate stack layer 110 may comprise a gate dielectric layer and a gate conductor layer. The gate dielectric layer may be formed of a high-k dielectric material. Examples of high-k dielectric materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k dielectric material may further include dopants such as lanthanum (La), aluminum (Al), and magnesium (Mg). The gate dielectric layer may have a uniform thickness.

The gate conductor layer may include a metal gate or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer as desired.

Source/drain regions 114a and source/drain regions 114b may be formed using epitaxial growth processes. Source/drain regions 114a and source/drain regions 114b may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (TI). In some embodiments, the epitaxy process comprises in-situ doping (dopants are incorporated in epitaxy material during epitaxy).

Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si: C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm⁻³, or preferably between 2×1020 cm-3 to 3×10²¹ cm⁻³. In some embodiments, source/drain regions 114a are p-type source/drain regions and source/drain regions 114b are n-type source/drain regions.

Sacrificial placeholder layers 116 are formed in substrate 102 and coplanar with STI regions 126. Sacrificial placeholder layers 116 can be comprised of a sacrificial material or materials, such as SiGe, titanium oxide (TiOₓ), aluminum oxide (AlOₓ), silicon carbide (SIC), etc.

ILD layer 118 is formed over gate stack layer 110 and source/drain regions 114a and source/drain regions 114b. ILD layer 118 may be formed of any suitable isolating material, such as SiO₂, SiOC, SiON, etc.

Semiconductor structure 100 further includes frontside source/drain contacts 120. Suitable metals for frontside source/drain contacts 120 include any conductive material such as, for example, a silicide liner such as Ti, Ni, NiPt, a metal adhesion layer TiN, TaN, and a conductive metal such as tungsten (W), aluminum (Al), copper (Cu), cobalt (Co), ruthenium (Ru), molybdenum (Mo), or any other suitable conductive material.

Semiconductor structure 100 further includes a frontside BEOL interconnect 122 having various BEOL interconnect structures and a carrier wafer 124. For example, frontside BEOL interconnect 122 is a metallization structure that includes one or more metal layers disposed on a side of semiconductor structure 100 opposite of the side on which the backside BEOL metallization structure is disposed. The metal layers of the frontside BEOL interconnect 122 each have metal lines for making interconnections to the semiconductor device. In particular, frontside BEOL interconnect 122 includes one or more metal layers that include metal lines for carrying power signals (e.g., a positive and/or negative voltage signal and/or ground signal) for providing power routing between the backside and the frontside of the semiconductor structure 100. Power routing involves metal lines configured to carry a power signal. For example, the semiconductor structure 100 may require power to operate. In the example of FETs as semiconductor structure 100, a power signal may need to be coupled to a gate, source, and/or drain of the FET for its desired function and operation.

Carrier wafer 124 may be formed of materials similar to that of substrate 102, and may be formed over frontside BEOL interconnect 122 using a wafer bonding process, such as dielectric-to-dielectric bonding.

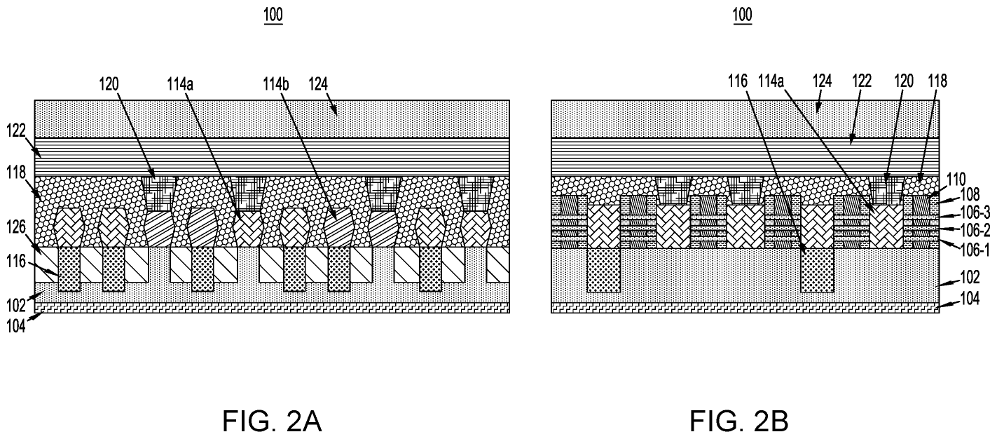

FIGS. 2A-2B illustrate semiconductor structure 100 at a second-intermediate fabrication stage. During this stage, the backside of substrate 102 is processed by, for example, flipping carrier wafer 124 over so that the backside of substrate 102 (i.e., the back surface) is facing up for backside processing. In particular, using the flipped structure, portions of substrate 102 may be removed from the backside using, for example, a substrate grinding, a planarization (e.g., using CMP) and a wet etch to selectively remove substrate 102 until etch stop layer 104 is reached.

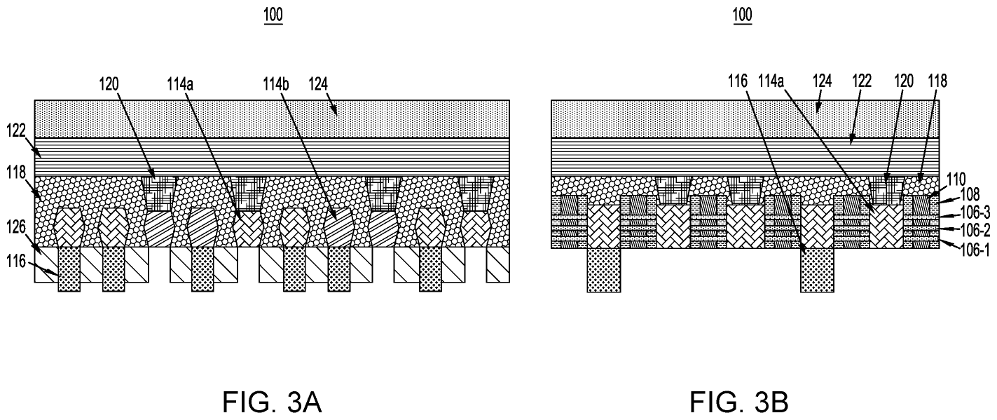

FIGS. 3A-3B illustrate semiconductor structure 100 at a third-intermediate fabrication stage. During this stage, etch stop layer 104 is selectively removed using, for example, a wet etch to selectively remove etch stop layer 104 until substrate 102 is reached. Next, the remaining portions of substrate 102 are removed to expose STI regions 126 and sacrificial placeholder layers 116, and given ones of source/drain regions 114a and source/drain regions 114b in contact with frontside source/drain contacts 120. The remaining portions of substrate 102 can be removed utilizing a selective etch process such as a wet etch.

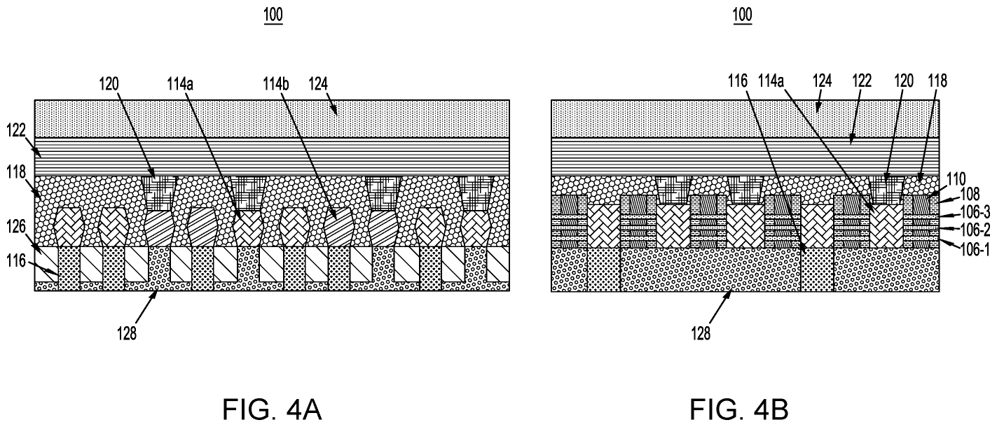

FIGS. 4A-4B illustrate semiconductor structure 100 at a fourth-intermediate fabrication stage. During this stage, a backside ILD layer 128 is deposited on the exposed STI regions 126, sacrificial placeholder layers 116, source/drain regions 114a and source/drain regions 114b using any conventional deposition technique such as ALD, CVD, PVD, etc., following by a planarization process (e.g., using CMP) to expose sacrificial placeholder layers 116 (see FIG. 4B). The backside ILD layer 128 may be formed of any suitable isolating material, such as SiO₂, SiOC, SiON, etc.

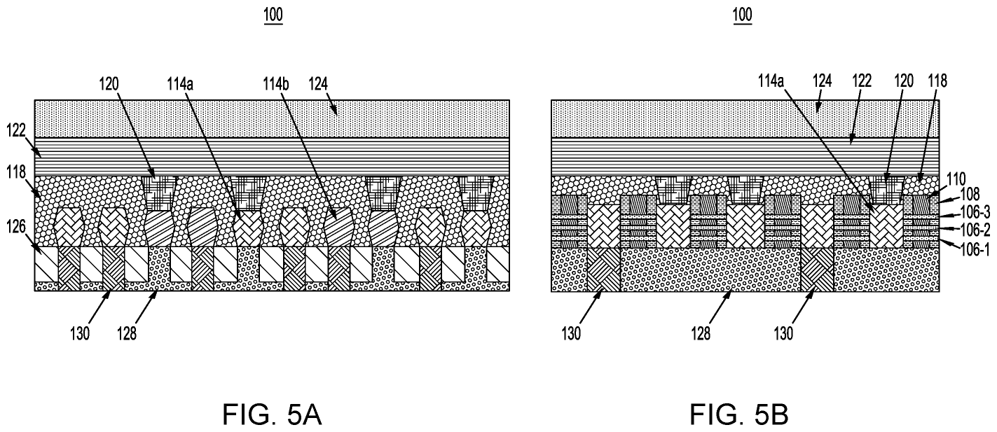

FIGS. 5A-5B illustrate semiconductor structure 100 at a fifth-intermediate fabrication stage. During this stage, the exposed sacrificial placeholder layers 116 are removed using any suitable etch processing that removes sacrificial placeholder layers 116 selective to that of the rest of the structure to form backside source/drain contact openings. A suitable etching process includes, for example, wet etch. Backside source/drain contacts 130 can be formed by depositing the conductive metal by ALD, CVD, PVD, and/or plating. The conductive metal can be planarized using, for example, a planarizing process such as CMP. Other planarization processes can include grinding and polishing. The conductive metal for backside source/drain contacts 130 can be a similar conductive metal as frontside source/drain contacts 120.

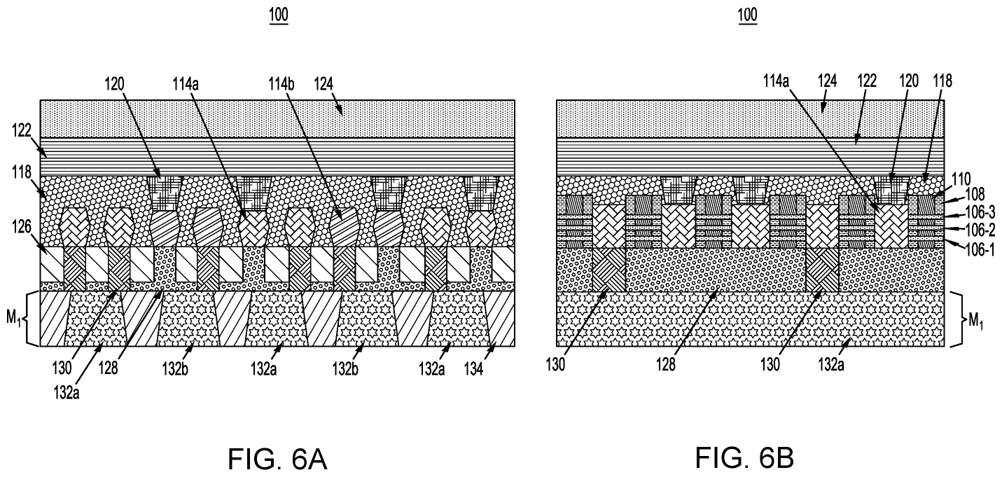

FIGS. 6A-6B illustrate semiconductor structure 100 at a sixth-intermediate fabrication stage. During this stage, a backside ILD layer 134 is deposited on semiconductor structure 100. Backside ILD layer 134 can be formed by similar processes and of a similar material as ILD layer 118. Next, a first metallization layer M1 is formed having backside power (Vdd) rails 132a to provide supply voltage to the structure, and backside ground (Vss) rails 132b to provide a series of power supplies by utilizing conventional lithographic and etching processes such as RIE in backside ILD layer 134 to create openings followed by depositing a suitable conductive metal in the openings. Backside power (Vdd) rails 132a and backside ground (Vss) rails 132b can be formed by similar processes and similar conductive metal as frontside source/drain contacts 120. The conductive metal can be planarized using, for example, a planarizing process such as CMP. Other planarization processes can include grinding and polishing.

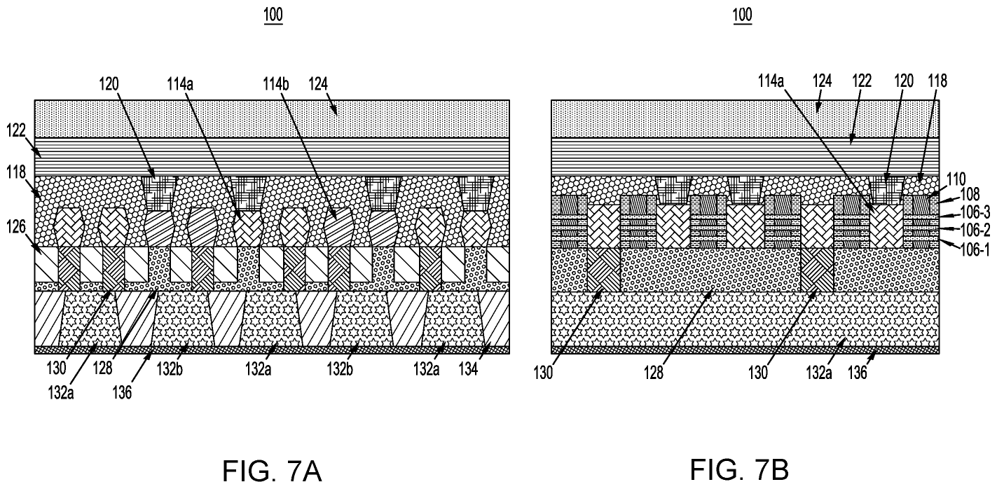

FIGS. 7A-7B illustrate semiconductor structure 100 at a seventh-intermediate fabrication stage. During this stage, a non-conductive liner 136 is deposited on semiconductor structure 100 using any convention deposition technique such as ALD, CVD, PVD, etc. In some embodiments, the non-conductive liner 136 can be a dielectric material such as, for example, SiN, HfO₂, HfZrO, etc. In some embodiments, the non-conductive liner 136 can include a stack of two or more layers. In one embodiment, a stack of two or more layers can include a stack of a ferroelectric material and a dielectric material. In one embodiment, suitable ferroelectric materials for a ferroelectric material layer includes, for example, mixed metal oxides such as BaTiO₃, Pb[ZrₓTi₁₋ₓ]O₃ (0≤1), and crystalline HfO₂ with a doping element selected from Zr, Al, Ca, Ce, Dy, Er, Gd, Ge, La, Sc, Si, Sr, Sn, and Y. In some embodiments, suitable dielectric material includes, for example, a nitride such as silicon carbon nitride, silicon nitride, etc.

In some embodiments, a stack of two or more layers can include a stack of an antiferroelectric material and a dielectric material. In an example embodiment, the dielectric layer may include an Hf-based compound, a Zr-based compound, and/or an Hf—Zr-based compound. For example, the Hf-based compound may be an HfO-based ferroelectric material or an HfO-based antiferroelectric material, the Zr-based compound may include a ZrO-based ferroelectric material or a ZrO-based antiferroelectric material, and the Hf—Zr-based compound may include a hafnium zirconium oxide (HZO)-based ferroelectric material or an HZO-based antiferroelectric material. In some embodiments, antiferroelectric properties may be initiated at higher dopant concentrations than ferroelectric properties. In some embodiments, the non-conductive liner 136 serves as a dielectric barrier layer to prevent the transmission of electrical current. In some embodiments, the dielectric material is HfZrO, wherein the Zr content can be varied to produce either a ferroelectric or antiferroelectric film. In some embodiments, the non-conductive liner 136 is formed with a single deposition flow starting with HfO₂ and then a Zr carrier gas is introduced to produce a HfO₂/HfZrO stack.

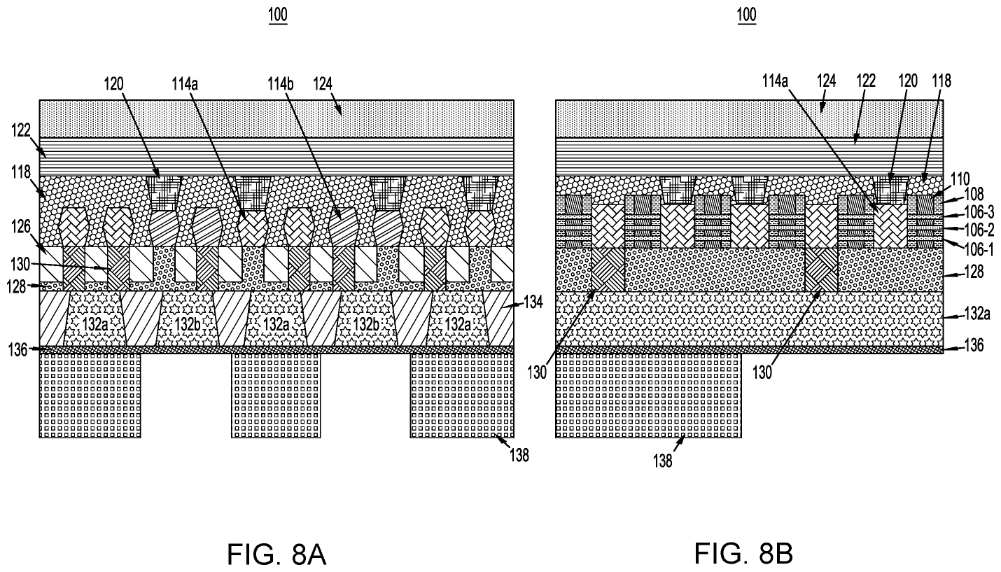

FIGS. 8A-8B illustrate semiconductor structure 100 at an eighth-intermediate fabrication stage. During this stage, a mask layer 138 (such as an organic planarization layer (OPL) or a spin-on-carbon (SOC)) is deposited on the non-conductive liner 136 using spin-on coating or any other suitable deposition process. Next, the mask layer 138 is patterned and a selective etch process such as RIE can be carried out to selectively remove the exposed portion of the mask layer 138 to form openings exposing the non-conductive liner 136.

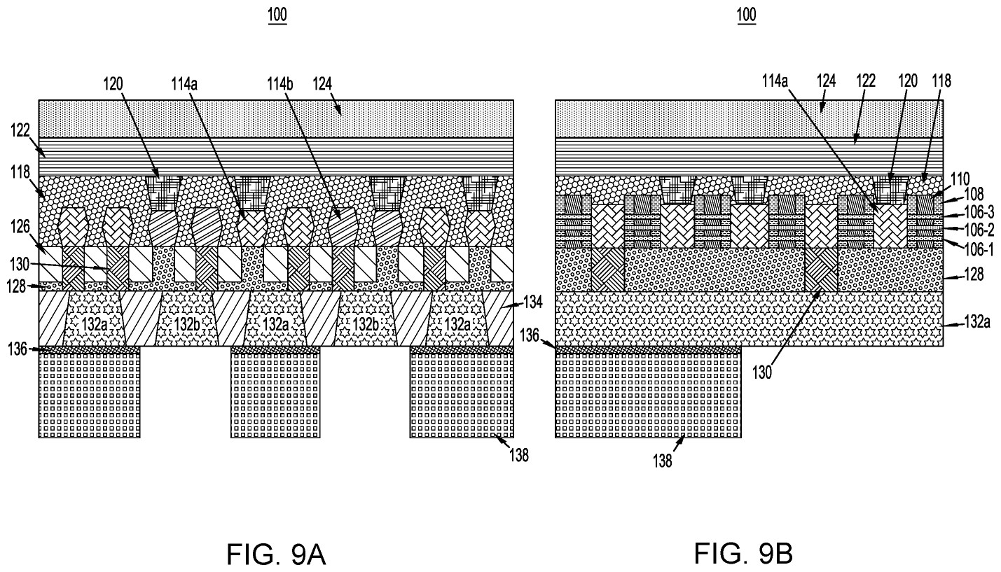

FIGS. 9A-9B illustrate semiconductor structure 100 at a ninth-intermediate fabrication stage. During this stage, the exposed portions of the non-conductive liner 136 are selectively removed using, for example, RIE, to expose backside ground (Vss) rails 132b (see FIG. 9A) and backside power (Vdd) rails 132a (see FIG. 9B).

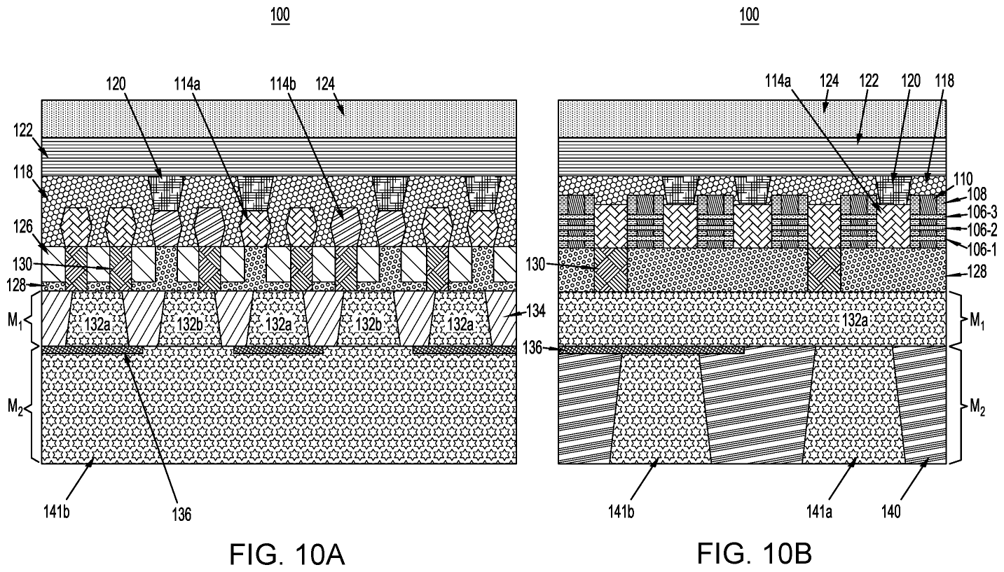

FIGS. 10A-10B illustrate semiconductor structure 100 at a tenth-intermediate fabrication stage. During this stage, mask layer 138 is removed using any known technique such as an ash etching process. Next, a backside ILD layer 140 is deposited on semiconductor structure 100. Backside ILD layer 140 can be formed by similar processes and of a similar material as ILD layer 118. Next, a second metallization layer M2 is formed having backside power (Vdd) rails 141a to provide supply voltage to the structure and backside ground (Vss) rails 141b to provide a series of power supplies by utilizing conventional lithographic and etching processes such as RIE in backside ILD layer 140 to create openings followed by depositing a suitable conductive metal in the openings. Backside power (Vdd) rails 141a and backside ground (Vss) rails 141b can be formed by similar processes and similar conductive metal as frontside source/drain contacts 120. The conductive metal can be planarized using, for example, a planarizing process such as CMP. Other planarization processes can include grinding and polishing.

FIGS. 10A and 10B further show that an interface between the first metallization layer, M₁, and the second metallization layer, M₂, is a uniform surface, i.e., a flat surface. In an illustrative embodiment, FIGS. 10A and 10B further show semiconductor structure 100 as a via-less semiconductor structure.

FIG. 10A further shows backside ground (Vss) rails 141b of second metallization layer M2 in contact with backside ground (Vss) rails 132b of first metallization layer M₁. FIG. 10A further shows backside ground (Vss) rails 141b of second metallization layer M2 being isolated from backside power (Vdd) rails 132a of first metallization layer M₁ by the non-conductive liner 136.

FIG. 10B further shows backside power (Vdd) rails 141a of second metallization layer M2 in contact with backside power (Vdd) rails 132a of first metallization layer M1. FIG. 10B further shows backside ground (Vss) rails 141b of second metallization layer M2 being isolated from backside power (Vdd) rails 132a of first metallization layer M₂ by the non-conductive liner 136. In this way, semiconductor structure 100 forms no via between backside of first metallization layer M₁ and second metallization layer M₂, and power rails of different voltage (e.g. Vdd, Vss) are separated only by the non-conductive liner 136 between the backside of first metallization layer M₁ and second metallization layer M₂, which, in turn, maximizes the coupling capacitance between backside power (Vdd) rails 132a and backside ground (Vss) rails 132b to improves the circuit performance.

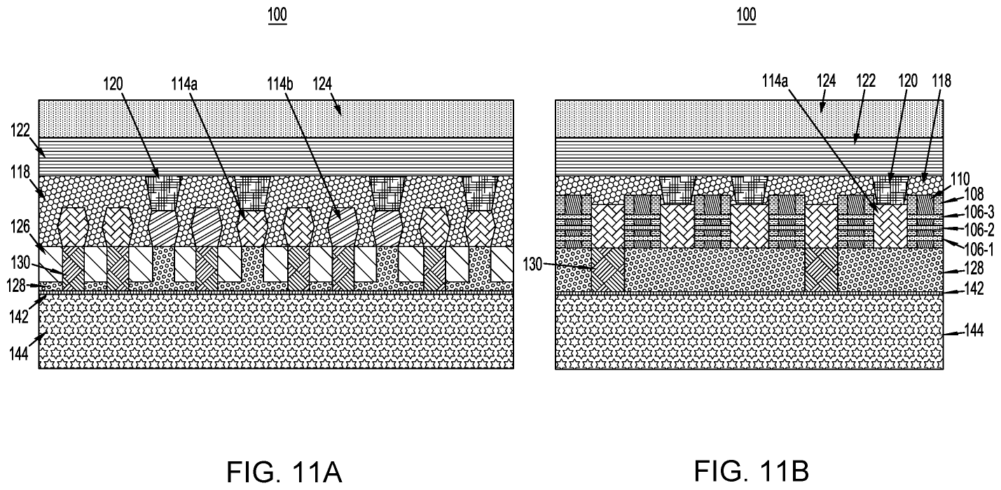

FIGS. 11A-11B illustrate an alternative embodiment of semiconductor structure 100 starting from FIGS. 5A-5B for use at a first-intermediate fabrication stage. During this stage, a liner layer 142 can be deposited over the exposed portions of backside ILD layer 128 and backside source/drain contacts 130 using any convention deposition technique such as ALD, CVD, PVD, etc., following by a planarization process e.g., using CMP). Suitable material for the liner layer 142 includes, for example, titanium nitride (TiN), tantalum nitride (TaN), etc.

Next, a metal layer 144 is deposited on the liner layer 142 using any convention deposition technique such as by ALD, CVD, PVD, and/or plating, followed by a planarization process (e.g., using CMP). Suitable conductive metals for metal layer 144 include, for example, cobalt, titanium, copper, aluminum (Al), tungsten (W), iridium (Ir), ruthenium (Ru), or alloys thereof. In various embodiments, metal layer 144 comprises Ru.

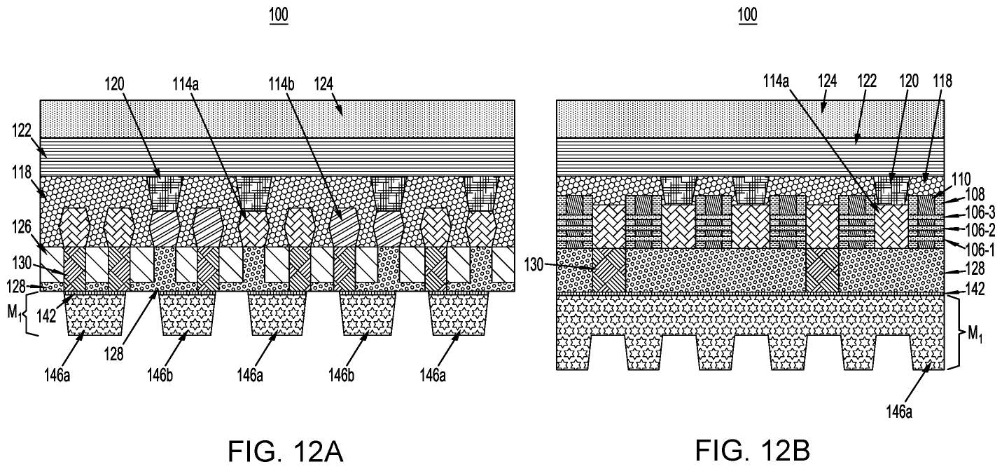

FIGS. 12A-12B illustrate an alternative embodiment of semiconductor structure 100 at a second-intermediate fabrication stage. During this stage, a subtractive metal patterning process is performed on metal layer 144 to form a first metallization layer M1 having backside power (Vdd) rails 146a to provide supply voltage to the structure, and backside ground (Vss) rails 146b to provide a series of power supplies. In the subtractive metal patterning process, a metal cut trench is formed in the metal layer 144. A portion of the liner layer 142 exposed by the metal cut trench is removed in the subtractive metal patterning process. FIG. 12A shows the subtractive metal patterning process forming a tapered metal cut trench between adjacent backside power (Vdd) rails 146a and backside ground (Vss) rails 146b. FIG. 12B shows the subtractive metal patterning process forming tapered metal cut trenches in backside ground (Vss) rails 146b.

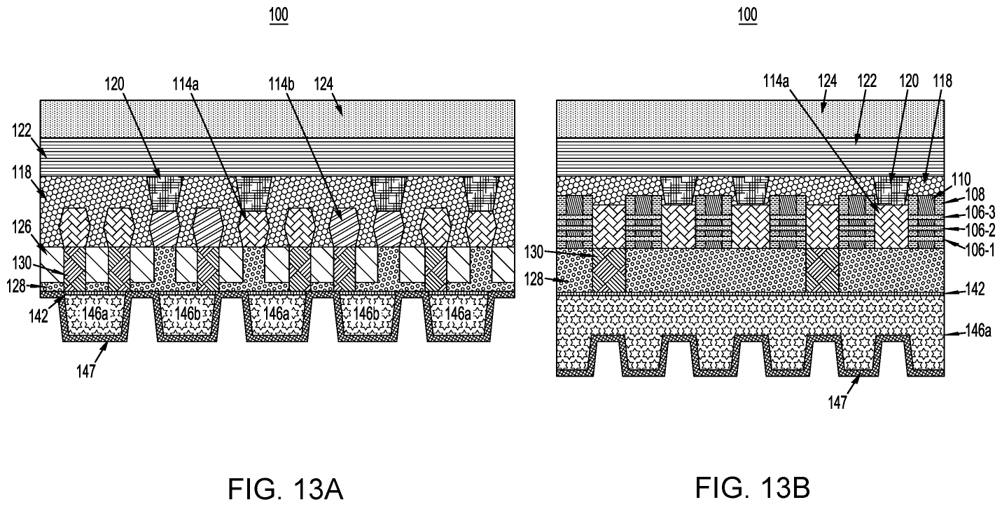

FIGS. 13A-13B illustrate an alternative embodiment of semiconductor structure 100 at a third-intermediate fabrication stage. During this stage, a non-conductive liner 147 is deposited on the exposed portions of backside ILD layer 128, backside power (Vdd) rails 146 and backside ground (Vss) rails 146b (sec FIG. 13A). FIG. 13B shows the non-conductive liner 147 deposited on the exposed portions of backside ground (Vss) rails 146b. The non-conductive liner 147 can be formed by similar processes and similar material as the non-conductive liner 136.

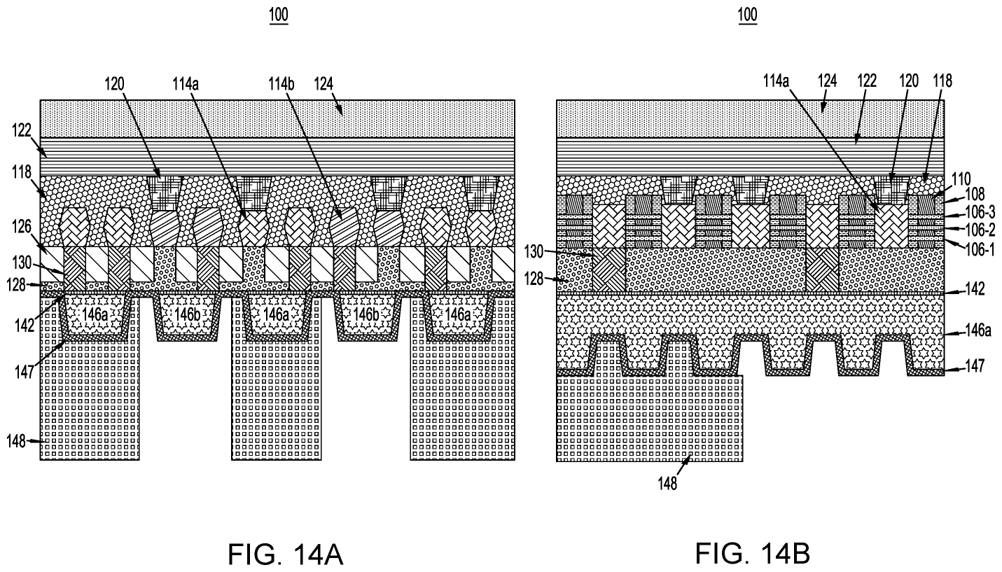

FIGS. 14A-14B illustrate an alternative embodiment of semiconductor structure 100 at a fourth-intermediate fabrication stage. During this stage, a mask layer 148 (such as an organic planarization layer (OPL) or a spin-on-carbon (SOC)) is deposited on the non-conductive liner 147 using spin-on coating or any other suitable deposition process. Next, the mask layer 148 is patterned and a selective etch process such as RIE can be carried out to selectively remove the exposed portion of the mask layer 148 to form openings exposing the non-conductive liner 147.

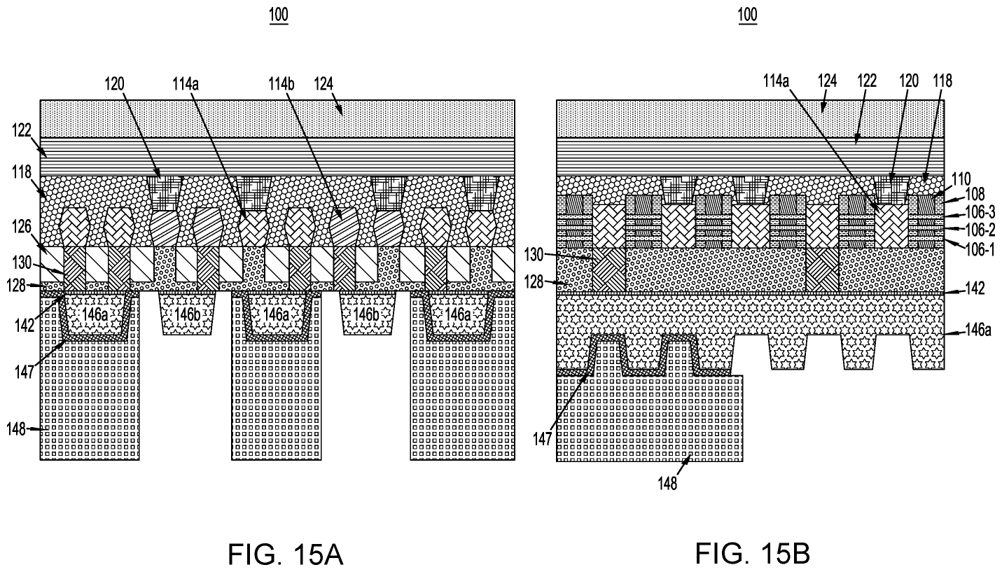

FIGS. 15A-15B illustrate an alternative embodiment of semiconductor structure 100 at a fifth-intermediate fabrication stage. During this stage, the exposed portions of the non-conductive liner 147 are selectively removed using, for example, RIE, to expose backside ground (Vss) rails 146b (see FIG. 15A) and backside power (Vdd) rails 146a (see FIG. 10B).

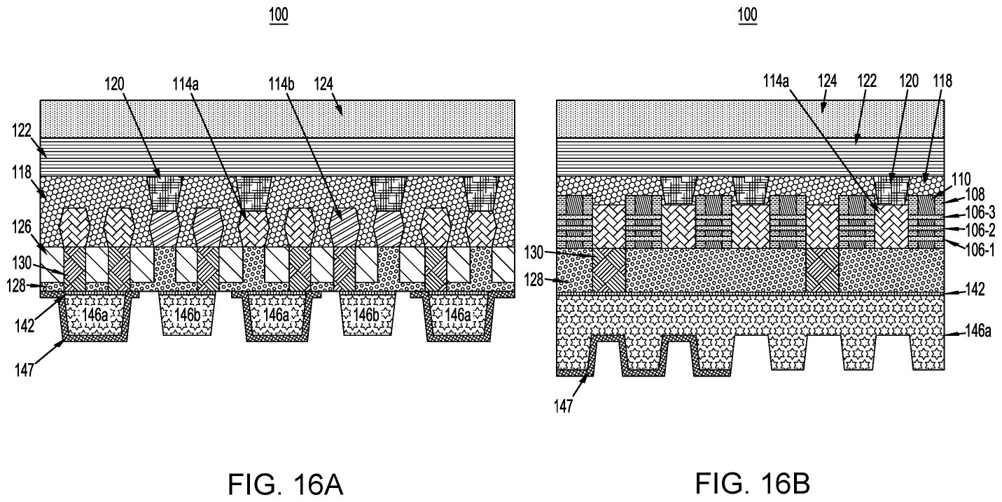

FIGS. 16A-16B illustrate an alternative embodiment of a semiconductor structure 100 at a sixth-intermediate fabrication stage. During this stage, mask layer 148 is removed using any known technique such as an ash etching process.

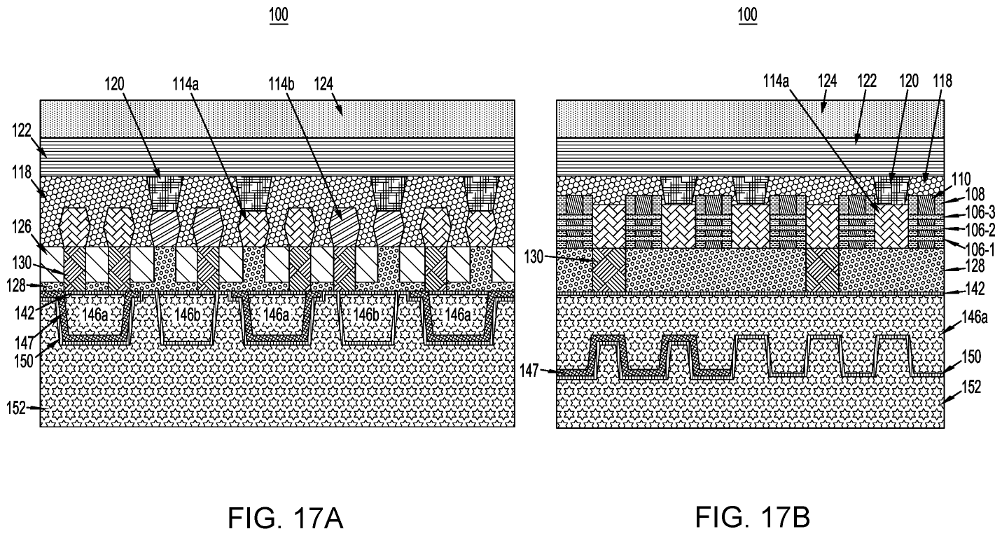

FIGS. 17A-17B illustrate an alternative embodiment of semiconductor structure 100 at a seventh-intermediate fabrication stage. During this stage, a liner layer 150 can be deposited over the exposed portions of backside ILD layer 128, the non-conductive liner 147, and backside ground (Vss) rails 146b (see FIG. 17A) and on the exposed portion of backside power (Vdd) rails 146a (see FIG. 17B), followed by depositing a metal layer 152 on liner layer 150. Liner layer 150 and metal layer 152 can be formed by similar processes and of a similar material as, respectively, the liner layer 142 and the metal layer 144.

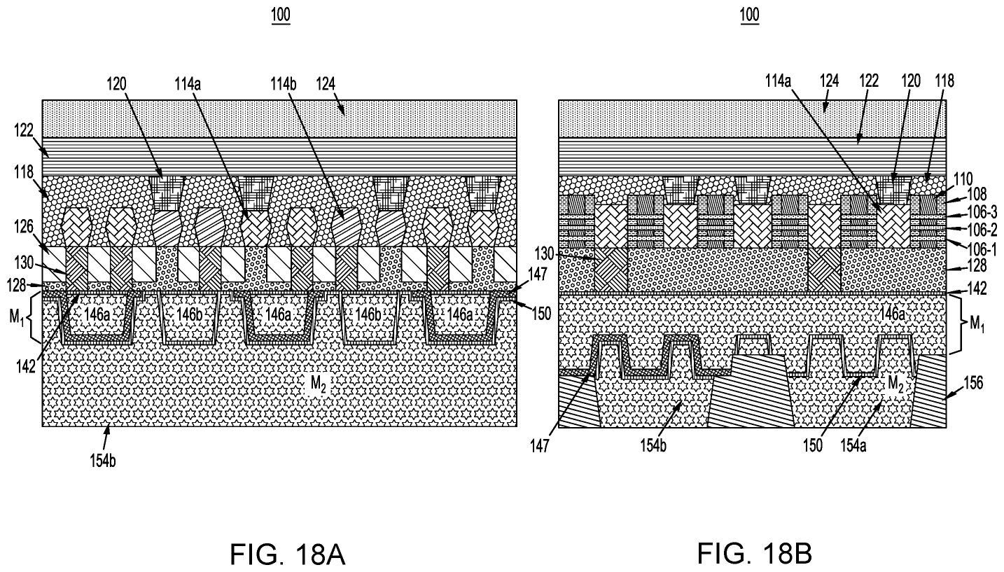

FIGS. 18A-18B illustrate an alternative embodiment of semiconductor structure 100 at an eighth-intermediate fabrication stage. During this stage, a second metallization layer M2 is formed by a subtractive metal patterning process performed on metal layer 152 to form openings followed by depositing a dielectric fill layer 156 to form backside power (Vdd) rails 154a and backside ground (Vss) rails 154b.

FIGS. 18A and 18B further show that an interface between the first metallization layer M₁ and the second metallization layer M2 is a non-uniform surface. In some embodiments, the non-uniform surface comprises a saw-shaped topography. In an illustrative embodiment, FIGS. 18A and 18B further show semiconductor structure 100 as a via-less semiconductor structure.

FIG. 18A further shows backside ground (Vss) rails 154b of second metallization layer M2 in contact with backside ground (Vss) rails 146b of first metallization layer M₁. FIG. 10A further shows backside ground (Vss) rails 154b of second metallization layer M₂ being isolated from backside power (Vdd) rails 146a of first metallization layer M₁ by the non-conductive liner 147.

FIG. 18B further shows backside power (Vdd) rails 154a of second metallization layer M₂ in contact with backside power (Vdd) rails 146a of first metallization layer M₁. FIG. 18B further shows backside ground (Vss) rails 154b of second metallization layer M₂ being isolated from backside power (Vdd) rails 146a of first metallization layer M₁ by the non-conductive liner 147. Accordingly, this further increases the overlap area between different power rails, between the backside of first metallization layer M₁ and second metallization layer M₂, to further increases the decoupling capacitance.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a backside interconnect comprising a first metal layer and a second metal layer disposed on the first metal layer, the first metal layer comprising a first Vdd metal line and a first Vss metal line, and the second metal layer comprising a second Vdd metal line and a second Vss metal line;
wherein the first Vss metal line is in contact with the second Vss metal line; and
wherein the second Vss metal line is isolated from the first Vdd metal line by a non-conductive liner.

2. The semiconductor structure of claim 1, wherein the first Vdd metal line is in contact with the second Vdd metal line.

3. The semiconductor structure of claim 1, wherein the non-conductive liner comprises a dielectric material comprising SiN and HfO₂.

4. The semiconductor structure of claim 1, wherein the non-conductive liner comprises a stack of ferroelectric material and dielectric material.

5. The semiconductor structure of claim 1, wherein the non-conductive liner comprises a stack of antiferroelectric material and dielectric material.

6. The semiconductor structure of claim 1, wherein an interface between the first metal layer and the second metal layer is a uniform surface.

7. The semiconductor structure of claim 1, wherein an interface between the first metal layer and the second metal layer is a non-uniform surface.

8. The semiconductor structure of claim 7, wherein the non-uniform surface comprises a saw-shaped topography.

9. The semiconductor structure of claim 8, wherein the first metal layer is patterned by a subtractive metal etching process.

10. The semiconductor structure of claim 7, wherein a TaN or a TiN liner layer is disposed between the first Vss metal line and the second Vss metal line.

11. The semiconductor structure of claim 2, wherein a TaN or a TiN liner layer is disposed between the first Vdd metal line and the second Vdd metal line.

12. A semiconductor structure, comprising:
a backside interconnect comprising a first metal layer and a second metal layer disposed on the first metal layer, the first metal layer comprising a first Vdd metal line, and the second metal layer comprising a second Vdd metal line and a Vss metal line;
wherein the first Vdd metal line is in contact with the second Vdd metal line; and
wherein the first Vdd metal line is isolated from the Vss metal line by a non-conductive liner.

13. The semiconductor structure of claim 12, wherein the non-conductive liner comprises a dielectric material comprising SiN and HfO₂.

14. The semiconductor structure of claim 12, wherein the non-conductive liner comprises a stack of ferroelectric material and dielectric material.

15. The semiconductor structure of claim 12, wherein the non-conductive liner comprises a stack of antiferroelectric material and dielectric material.

16. The semiconductor structure of claim 12, wherein an interface between the first metal layer and the second metal layer is a uniform surface.

17. The semiconductor structure of claim 12, wherein an interface between the first metal layer and the second metal layer is a non-uniform surface.

18. The semiconductor structure of claim 17, wherein the non-uniform surface comprises a saw-shaped topography.

19. The semiconductor structure of claim 17, wherein a TaN or a TiN liner layer is disposed between the first Vdd metal line and the second Vdd metal line.

20. An integrated circuit, comprising:
one or more semiconductor structures, wherein at least one of the one or more semiconductor structures comprises:
a backside interconnect comprising a first metal layer and a second metal layer disposed on the first metal layer, the first metal layer comprising a first Vdd metal line and a first Vss metal line, and the second metal layer comprising a second Vdd metal line and a second Vss metal line;
wherein the first Vss metal line is in contact with the second Vss metal line; and
wherein the second Vss metal line is isolated from the first Vdd metal line by a non-conductive liner.
